(19) United States
(12) Patent Application Publication
(10) Pub. No.: US 2017/0003367 A1
(43) Pub. Date: Jan. 5, 2017

(54) MAGNETIC RESONANCE IMAGING SYSTEM AND METHOD

(71) Applicant: General Electric Company, SCHENECTADY, NY (US)

(72) Inventors: DASHEN CHU, HARTLAND, WI (US); ROBERT STEVEN STORMONT, HARTLAND, WI (US); SCOTT ALLEN LINDSAY, DOUSMAN, WI (US); JAMES HIROSHI AKAO, BROOKFIELD, WI (US); ZHU LI, WAUKESHA, WI (US); HAI ZHENG, PEWAUKEE, WI (US); XIAOXU LIU, HARTLAND, WI (US)

(73) Assignee: GENERAL ELECTRIC COMPANY, SCHENECTADY, NY (US)

(21) Appl. No.: 14/754,836

(22) Filed: Jun. 30, 2015

(51) Int. Cl. G01R 33/561; G01R 33/341; G01R 33/36; G01R 33/34

(52) U.S. Cl. CPC G01R 33/5612; G01R 33/34076; G01R 33/341; G01R 33/3614

(57) ABSTRACT

A method of parallel imaging for use with a magnetic resonance imaging apparatus includes producing a longitudinal magnetic field B0 throughout a target volume, producing a transverse magnetic field B1 that is generally perpendicular to B0 throughout the target volume, transmitting a plurality of RF pulses to the target volume, with a surface coil, acquiring first MRI data from a target within the target volume in response to the transmission of RF pulses, and with a body coil, acquiring second MRI data from the target within the target volume in response to the transmission of RF pulses, wherein acquisition of the first MRI data and the second MRI data occurs substantially simultaneously.

### BACKGROUND

Technical Field

Embodiments of the invention relate generally to magnetic resonance imaging and, more specifically, to a system and method to improve the parallel imaging performance of a magnetic resonance imaging device.

Discussion of Art

Generally, magnetic resonance images are obtained by imposing on a target object, such as a patient's body, a large uniform magnetic field (“B0”) from a “field” or “polarizing” coil. This large uniform field substantially aligns the quantum spins of protons in the molecules within the target object, although the spins of protons within chemically distinct molecules will continue to process at distinct Larmor frequencies. By briefly imposing a pulsed RF field (“B1”) from a “transmit coil,” generally transverse to B0, it is possible to excite the protons of molecules with spins that process at a Larmor frequency matching the pulsed RF. As the excited protons relax back to their lower energy normal state, they emit RF energy that can be detected by a “receive coil,” which may be the same as, or separate from, the transmit coil. The detected RF energy is recorded as intensity data that then is processed, by known means, so as to obtain a visual approximation or image of where and how the various chemicals are disposed within the target object.

As mentioned, RF coils are used in an MRI system to transmit RF excitation signals and to receive MR signals emitted by an imaging subject. Various types of RF coils may be utilized in an MRI system such as a whole-body coil and RF surface (or local) coils. Typically, the whole-body RF coil is used for transmitting the RF excitation signals, although a whole-body RF coil may also be configured to receive MRI signals. One or more (e.g., an array) surface coils can be used as the receive coils to detect MRI signals or, in certain applications, to transmit RF excitation signals. Surface coils may be placed in close proximity to a region of interest in a subject and, for reception, typically yield a higher signal-to-noise ratio (SNR) than a whole-body RF coil.

In connection with the above, an array of surface RF coils can be used for “parallel imaging,” a technique developed to accelerate MR data acquisition and reduce scan time. In parallel imaging, multiple receive RF coils acquire (or receive) data from a region or volume of interest. In general, parallel imaging acceleration rates are dependent on the geometry factor (“g-factor”), which itself depends on coil geometry and coil channel density of the receive coil array. Accordingly, common practice has been to utilize smaller size coil elements to increase coil density in order to achieve high acceleration parallel imaging since smaller size coil elements and high channel counts have been shown to yield better (smaller) geometry factor. Such existing techniques, however, may result in the reduction of B1 penetration in the regions of interest, which directly reduces the base SNR of the array. This can ultimately diminish or even negate the gain from the improvement of geometry factor for overall parallel imaging performance, which is dependent not only on g-factors, but also on the base SNR of the images, as evidenced by the equation:

SNRπ=SNR_{base}/(g*√(R)), (1)

where SNRπ is the parallel imaging SNR, SNR_{base} is the base SNR without accelerations, and R is scan time reduction factor.

What is needed, therefore, is a system and method that improves overall parallel imaging performance and, in particular, a system and method that improves parallel imaging acceleration rates without reducing the base SNR of the array.

### BRIEF DESCRIPTION

In an embodiment, a method of parallel imaging for use with a magnetic resonance imaging apparatus is provided. The method includes the steps of producing a longitudinal magnetic field B0 throughout a target volume, producing a transverse magnetic field B1 that is generally perpendicular to B0 throughout the target volume, transmitting a plurality of RF pulses to the target volume, with a surface coil, acquiring first MRI data from a target within the target volume in response to the transmission of RF pulses, and with a body coil, acquiring second MRI data from the target within the target volume in response to the transmission of RF pulses. Acquisition of the first MRI data and the second MRI data occurs substantially simultaneously.

In an embodiment, magnetic resonance imaging system is provided. The system includes a body coil assembly surrounding a target volume, the body coil assembly being configured to transmit a plurality of RF pulses to the target volume in a transmit mode, and a surface coil assembly arrange proximate to the target volume, the surface coil assembly being electrically coupled to a plurality of first receive channels configured to receive first RF signals from a target within the target volume. The body coil assembly is electrically coupled to a plurality of second receive channels configured to receive second RF signals from the target in a receive mode. The second RF signals are acquired by the volume coil and the first RF signals are acquired by the surface coil assembly simultaneously.

In an embodiment, a method of parallel imaging for use with a magnetic resonance imaging apparatus is provided. The method includes the steps of transmitting a plurality of RF pulses to a target volume with a body coil operating in a body coil transmit mode, acquiring first magnetic resonance signals from a target within the target volume with a surface coil operating in a surface coil receive mode, reducing mutual couplings between the body coil and the surface coil with the body coil operating in a body coil receive mode, and acquiring second magnetic resonance signals from the target within the target volume with the body coil operating in the body coil receive mode, wherein acquisition of the first magnetic resonance signals and the second magnetic resonance signals occurs substantially simultaneously.

### DRAWINGS

The present invention will be better understood from reading the following description of non-limiting embodiments, with reference to the attached drawings, wherein below:

FIG. 1 depicts schematically an exemplary magnetic resonance imaging (MRI) system that incorporates embodiments of the invention.

FIG. 2 is schematic diagram of a parallel LC resonance circuit that is operatively connected with the body coil feeding loop of the MRI system shown in FIG. 1.

FIG. 3 is a schematic illustration of a birdcage body coil of the MRI system shown in FIG. 1.

FIG. 4 is an axial view of the birdcage body coil of FIG. 3.

FIG. 5 is a diagram showing simulation results of B1 map of a 4 port feeding birdcage body coil as compared to a traditional 2 port feeding design.

### DETAILED DESCRIPTION

Reference will be made below in detail to exemplary embodiments of the invention, examples of which are illustrated in the accompanying drawings. Wherever possible, the same reference characters used throughout the drawings refer to the same or like parts, without duplicative description. Although exemplary embodiments of the present invention are described with respect to an MRI body (transmit) coil and an MRI surface (receive) coil array, embodiments of the invention also may be applicable for use with parallel-coil RF transceivers, generally.

As used herein, the terms “substantially,” “generally,” and “about” indicate conditions within reasonably achievable manufacturing and assembly tolerances, relative to ideal desired conditions suitable for achieving the functional purpose of a component or assembly. As used herein, “electrically coupled, “electrically connected” and “electrical communication” means that the referenced elements are directly or indirectly connected such that an electrical current may flow from one to the other. The connection may include a direct conductive connection (i.e., without an intervening capacitive, inductive or active element), an inductive connection, a capacitive connection, and/or any other suitable electrical connection. Intervening components may be present.

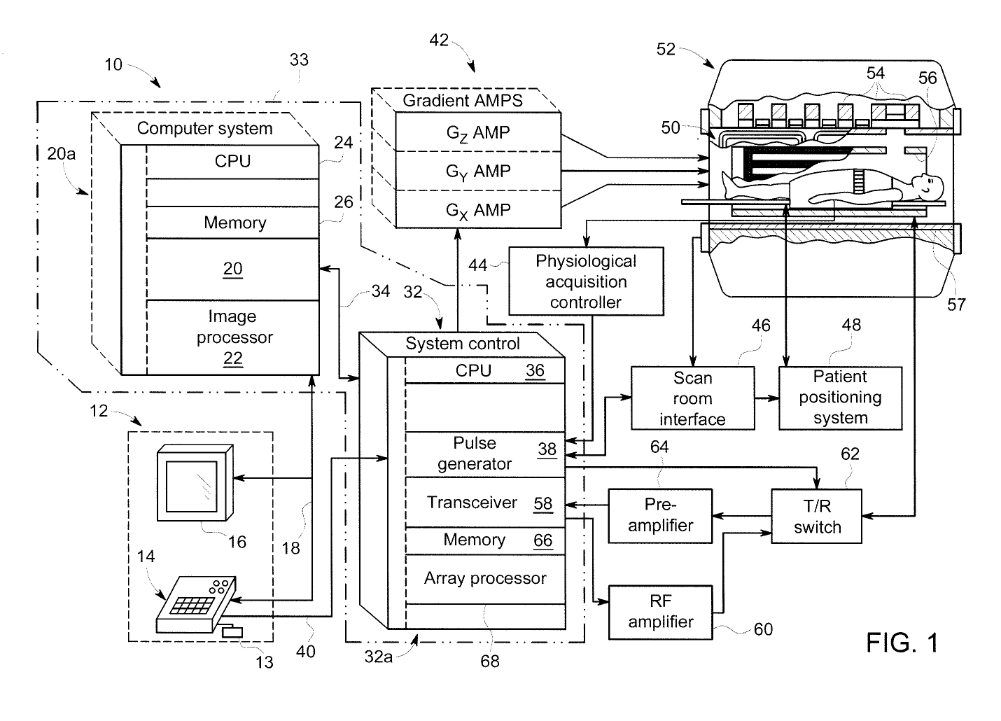

FIG. 1 shows major components of an exemplary magnetic resonance imaging (MRI) system 10 that incorporates embodiments of the present invention. The operation of the system is controlled from an operator console 12, which includes a keyboard or other input device 13, a control panel 14, and a display screen 16. The input device 13 can include a mouse, joystick, keyboard, track ball, touch activated screen, light wand, voice control, or any similar or equivalent input device, and may be used for interactive geometry prescription. The console 12 communicates through a link 18 with a separate computer system 20 that enables an operator to control the production and display of images on the display screen 16. The computer system 20 includes a number of modules that communicate with each other through a backplane 20a.

The modules of the computer system 20 include an image processor module 22, a CPU module 24 and a memory module 26 that may include a frame buffer for storing image data arrays. The computer system 20 is linked to archival media devices, permanent or back-up memory storage or a network for storage of image data and programs, and communicates with a separate MRI system control 32 through a high-speed signal link 34. The computer system 20 and the MRI system control 32 collectively form an “MRI controller” 33.

The MRI system control 32 includes a set of modules connected together by a backplane 32a. These include a CPU module 36 as well as a pulse generator module 38. The CPU module 36 connects to the operator console 12 through a data link 40. It is through link 40 that the MRI system control 32 receives commands from the operator to indicate the scan sequence that is to be performed. The CPU module 36 operates the system components to carry out the desired scan sequence and produces data which indicates the timing, strength and shape of the RF pulses produced, and the timing and length of the data acquisition window. The CPU module 36 connects to several components that are operated by the MRI controller 33, including the pulse generator module 38 (which controls a gradient amplifier 42, further discussed below), a physiological acquisition controller (“PAC”) 44, and a scan room interface circuit 46.

The CPU module 36 receives patient data from the physiological acquisition controller 44, which receives signals from a number of different sensors connected to the patient, such as ECG signals from electrodes attached to the patient. And finally, the CPU module 36 receives from the scan room interface circuit 46, signals from various sensors associated with the condition of the patient and the magnet system. It is also through the scan room interface circuit 46 that the MRI controller 33 commands a patient positioning system 48 to move the patient or client C to a desired position for the scan.

The pulse generator module 38 operates the gradient amplifiers 42 to achieve desired timing and shape of the gradient pulses that are produced during the scan. The gradient waveforms produced by the pulse generator module 38 are applied to the gradient amplifier system 42 having Gx, Gy, and Gz amplifiers. Each gradient amplifier excites a corresponding physical gradient coil in a gradient coil assembly, generally designated 50, to produce the magnetic field gradients used for spatially encoding acquired signals. The gradient coil assembly 50 forms part of a magnet assembly 52, which also includes a polarizing magnet 54 (which, in operation, provides a homogeneous longitudinal magnetic field 130 throughout a target volume 55 that is enclosed by the magnet assembly 52) and a whole-body (transmit and receive) RF coil 56 (which, in operation, provides a transverse magnetic field B1 that is generally perpendicular to B0 throughout the target volume 55).

In an embodiment of the invention, RF coil 56 is a multi-channel coil. The MRI apparatus 10 also includes a surface (receive) coil 57, which may be single or multi-channel. A transceiver module 58 in the MRI system control 32 produces pulses that are amplified by an RF amplifier 60 and coupled to the RF coil 56 by a transmit/receive switch 62. The resulting signals emitted by the excited nuclei in the patient may be sensed by the same RF coil 56, as well as by the dedicated receive coil 57, and coupled through the transmit/receive switch 62 to a preamplifier 64. The amplified MR signals are demodulated, filtered, and digitized in the receiver section of the transceiver 58. The transmit/receive switch 62 is controlled by a signal from the pulse generator module 32 to electrically connect the RF amplifier 60 to the coil 56 during the transmit mode and to connect the preamplifier 64 to the coil 56 during the receive mode. The transmit/receive switch 62 can also enable the surface RF coil 57 to be used in either transmit mode or receive mode.

Conventionally, the surface coil 57 in its receive mode would be coupled to (resonant at the same frequency as) the body coil 56, so as to best receive echoes of the RF pulse transmitted during the transmit mode. However, in case the surface RF coil 57 is not being used for transmission, then it would be necessary to decouple the surface coil 57 from the body coil 56 while the body coil 56 is transmitting the RF pulse. Conventionally, decoupling would be accomplished using diodes to activate a detuning circuit operatively connected with the surface coil 57. Other methods for decoupling are also known in the art, such as those described in U.S. Pat. No. 8,207,736, which is incorporated by reference herein.

After the multi-channel RF coil 56 and/or the surface coil 57 picks up the RF signals produced from excitation of the target, the transceiver module 58 digitizes these signals. The MRI controller 33 then processes the digitized signals by Fourier transform to produce k-space data, which then is transferred to a memory module 66, or other computer readable media, via the MRI system control 32. “Computer readable media” may include, for example, structures configured so that electrical, optical, or magnetic states may be fixed in a manner perceptible and reproducible by a conventional computer: e.g., text or images printed to paper or displayed on a screen, optical discs, or other optical storage media; “flash” memory, EEPROM, SDRAM, or other electrical storage media; floppy or other magnetic discs, magnetic tape, or other magnetic storage media.

A scan is complete when an array of raw k-space data has been acquired in the computer readable media 66. This raw k-space data is rearranged into separate k-space data arrays for each image to be reconstructed, and each of these is input to an array processor 68 which operates to Fourier transform the data into an array of image data. This image data is conveyed through the data link 34 to the computer system 20 where it is stored in memory. In response to commands received from the operator console 12, this image data may be archived in long-term storage or it may be further processed by the image processor 22 and conveyed to the operator console 12 and presented on the display 16.

In order to improve overall parallel imaging performance and, in particular, to improve parallel imaging acceleration rates without reducing the base SNR of the coil array, the present invention contemplates the utilization of the receive channels of the body coil 56 in addition to the receive channels of the surface coil 57 in receive mode. In particular, in an embodiment, the MRI system 10 utilizes the signals from the body coil channels simultaneously acquired with the surface coil arrays to further improve parallel imaging performance of MRI.

For example, in an embodiment, the surface coil 57 has a plurality of receive channels, such as N number of receive channels, configured to pick up the RF signals produced from excitation of the target, wherein N is any integer greater than 0. In addition to the N receive channels of the surface coil 57, the RF signals produced from excitation of the target are also acquired by two receive channels of the body coil 56. In an embodiment, the body coil 56 is a birdcage body coil. Adding two receive channels of the birdcage body coil 56 to an N-channel surface array will increase the channel count of the whole receive coil assembly array from an N-channel surface coil array to an N+2 channel array. This higher receive channel count within the field of view (FOV) results in smaller g-factor and thus higher acceleration.

As alluded to above, typically, body coils and receive coils are mutually exclusive. In transmit mode, the body coils 56 would typically be enabled to transmit RF pulses and the receive coils (typically the surface coil 57) would be disabled or decoupled. Similarly, in reception mode, the receive coils (i.e., the surface coil array(s)) 57) would be enabled due to their high SNR for MR signal receptions while body coils 56 would be disabled. Indeed, mutual couplings between body coils 56 and the surface coils 57 can degrade image quality.

In connection with the above, in order to utilize the two receive channels of the birdcage body coil 56 simultaneously with the receive channels of the surface coil 57 without compromising overall performance of the system 10, namely, without achieving higher imaging acceleration rates at the expense of image quality, a specific body feeding scheme may be utilized to reduce mutual couplings between the RF coils.

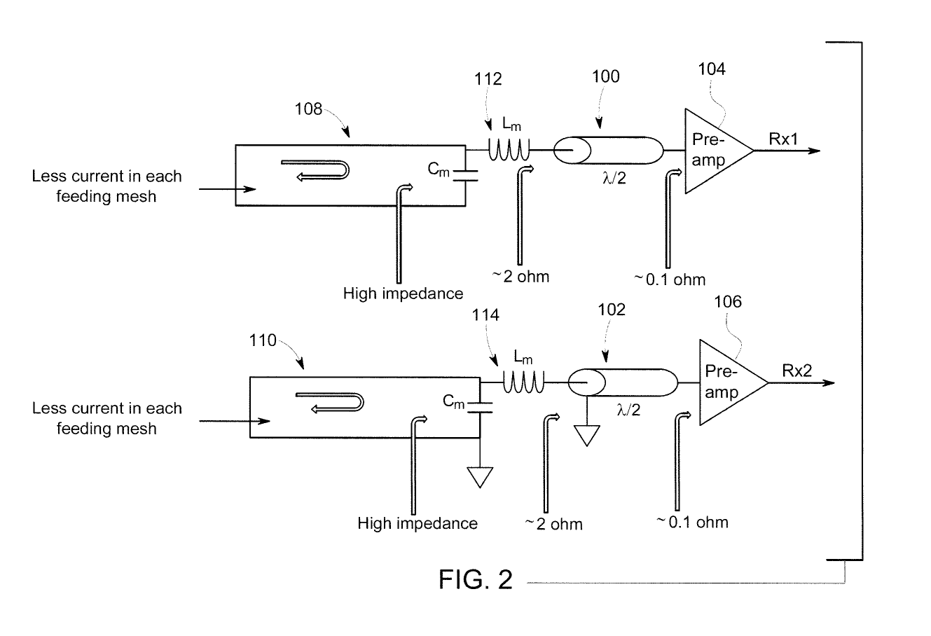

With reference to FIGS. 2-7 a pre-amplifier interface scheme is applied to the body coil 56 in order to reduce mutual couplings between the body coil 56 and the surface coil arrays 57. In particular, the pre-amplifier decoupling technique utilizes low input impedance pre-amplifiers to generate a high blocking impedance to reduce RF current in the body coil loops while receiving MR signals from the connected coil loop. Reduction of the RF current in each coil element of the coil arrays results in reduction of mutual couplings between coil elements of the RF arrays. More specifically, reduction of current in the body coil 56 results in reduction of inductive coupling between the receive surface coil arrays 57 and the body coil 56. As a result, the two receive channels of the body coil 56 may be utilized simultaneously with the receive channels of the surface coil array 57 to achieve higher imaging acceleration rates without substantially reducing the base SNR of the array and therefor without compromising overall performance.

With particular reference to FIG. 2, a half wave transmission line 100, 102 similar to the receive surface coil design may be utilized to connect low input impedance pre-amplifiers 104, 106 and each body coil feeding loop 108, 110. Pre-amp low input impedance is transferred to the feeding or matching points. The matching circuit, for example a parallel LC resonance circuit 112, 114, creates high blocking impedance.

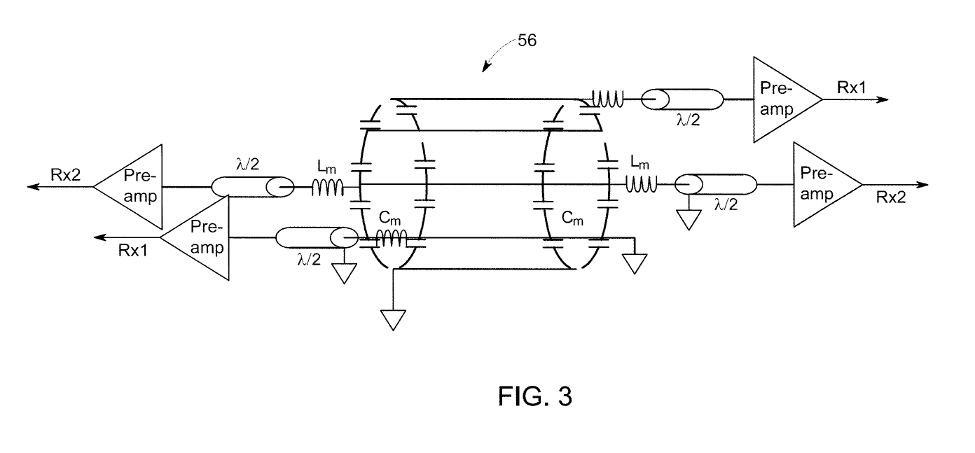

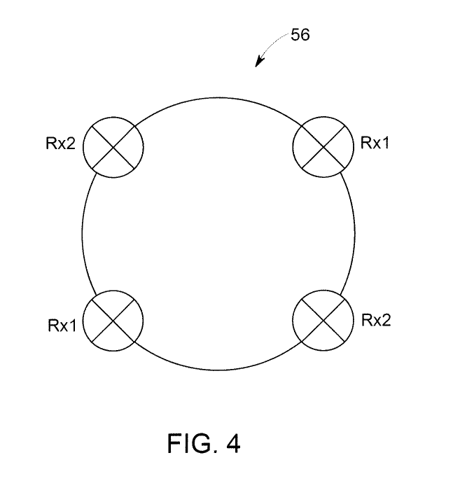

The resultant high impedance reduces or blocks the flowing current in each feeding loop of the body coils 56. As a result, mutual inductive couplings between surface receive coils 57 and the body coils 56 are reduced in receive mode. As will be readily appreciated, however, simply creating high impedance at arbitrary feeding loops or points destroy the symmetry of the birdcage body coil 56, which is needed to generate symmetric and uniform receive B1 field map. To preserve the symmetry of the birdcage body coil 56 while creating some high impedance points, four ports are utilized to feed or receive the signals. In an embodiment, the four ports are distributed every ninety degrees along the birdcage end rings. FIGS. 3 and 4 depict a four-port feeding birdcage body coil 56 in receive mode.

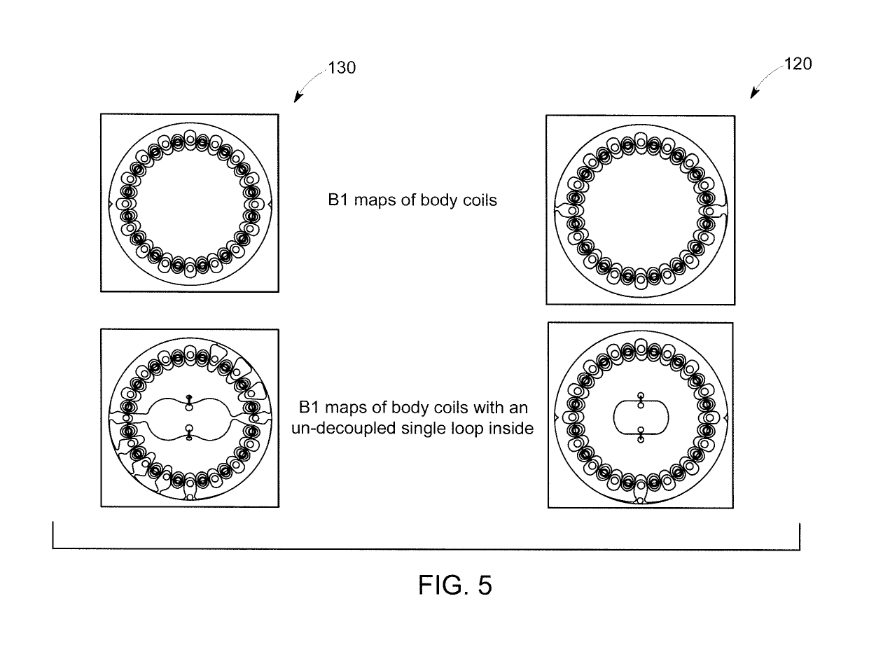

Due to pre-amp soft decoupling, every ring of the birdcage body coil 56 does not share the same impedance. The created high impedance points are distributed right-left and anterior position symmetrically. FIG. 5 illustrates simulation results of B1 map of the 4-port feeding birdcage 56 with pre-amp decoupling (shown at 120), which is the same as the traditional 2-port feeding birdcage design (shown at 130). As will be readily appreciated, the four high impedance meshes do not affect the B1 uniformity at all.

As will be readily appreciated, this technique enables both the surface coil array and the body coil to operate in receive mode with less mutual coupling to achieve better signal to noise ratio. In particular, this allows two receive channels of the body coil 56 to be utilized simultaneously with the receive channels of the surface coil 57 in order to achieve a higher channel count within the field of view which, in turn, results in smaller g-factor and higher parallel imaging SNR. Since the pre-amp soft decoupling from the body coil 56 provides extra decoupling in receive mode, the technique reduces active decoupling circuits needed on the surface coil array 57. Such reduction in active decoupling circuits provides high intrinsic SNR of the body coil 56, as decoupling circuits generate noise as a side effect.

In general, the use of two receive channels of the birdcage body coil 56 of the MRI system 10 to acquire MR signals simultaneously with the receive channels of the surface coil array 57 improves overall parallel imaging performance, including SNR improvement and scan time reductions, by improving both base SNR and g-factors. In an embodiment, the system 10 may be utilized for torso abdomen imaging, where the addition of two channel receivers from the birdcage body coil 56 can enhance the base SNR in deep tissues and reduce the g-factor, although the present invention is not intend to limited to any particular application. Regardless of application, the present invention utilizes volume coils, such as birdcage body coils, in addition to local surface coils to improve parallel imaging performance with both improved g-factor and base SNR.

In an embodiment, the present invention contemplates new parallel imaging application, such as enabling accelerated parallel imaging in the AP direction without resorting to the use of anterior surface coils.

In yet other embodiments, g-factor may be reduced and base SNR improved for an assembly of surface coil arrays and a birdcage body coil by adding birdcage body coil sensitivity, including B1 phase information, to surface coil arrays. In connection with this, birdcage body coils have been known for their spatial homogeneity and have been mainly used for transmitting RF pulses, as discussed herein. It has heretofore been thought that adding two channels form a body coil adds little value for changing g-factor since g-factors heavily rely on the magnetic field B1 spatial information. Indeed, a spatially uniform B1 will not contribute to g-factor at all.

However, relative homogeneous B1 distribution of a birdcage coil only exists in a vacuum or non-conductive medium, such as silicon oil phantoms. B1 of a birdcage coil inside human tissues becomes increasingly inhomogeneous as magnetic field strength increases due to wavelength effects. As often observed, the images acquired from silicon oil phantoms is much more uniform than acquired from in vivo imaging at 3T since both magnitudes and phase of B1 from I and Q channels of a birdcage body coil are distorted.

Furthermore, g-factor calculations resort to not only the magnitude but also the phase spatial distribution of coil B1 sensitivities. Even through the magnitude of a birdcage body coil in a vacuum is relatively uniform, it has been discovered that the B1 phase of a birdcage body coil display significant spatial variations in a vacuum. Accordingly, in an embodiment, both intrinsic phase spatial variations and induced B1 variations in magnitude and phase of B1 of birdcage body coil sensitivity can be used to further improve overall g-factor of the whole assembly array, such as the N-channel surface coil array plus a 2-channel birdcage body coil described above.

While the embodiments of the present invention described above disclose the use of receive channels of a birdcage body coil to acquire MRI data simultaneously with the receive channels of a surface coil assembly, the present invention is not so limited in this regard. In particular, it is contemplated that other types of body coils or body coil arrays can be utilized in a similar manner to simultaneously acquire MRI data. For example, the body coil may be a transverse electromagnetic (TEM) volume coil having, typically, 8 to 32 channels. In connection with this, because of the numerous channels, multiple preamplifiers may be utilized to decouple from the surface coils and achieve improved parallel imaging performance similar to the embodiments described above.

In an embodiment, a method of parallel imaging for use with a magnetic resonance imaging apparatus is provided. The method includes the steps of producing a longitudinal magnetic field B0 throughout a target volume, producing a transverse magnetic field B1 that is generally perpendicular to B0 throughout the target volume, transmitting a plurality of RF pulses to the target volume, with a surface coil, acquiring first MRI data from a target within the target volume in response to the transmission of RF pulses, and with a body coil, acquiring second MRI data from the target within the target volume in response to the transmission of RF pulses. Acquisition of the first MRI data and the second MRI data occurs substantially simultaneously The method may also include the step of reducing mutual couplings between the body coil and the surface coil during MRI data acquisition. In an embodiment, the step of reducing mutual couplings between the body coil and the surface coil includes generating a high blocking impedance to reduce RF current in the body coil while receiving the second MRI data. In an embodiment, the body coil is a birdcage body coil. In an embodiment, the high blocking impedance is generated at four points on the birdcage body coil, the four points being distributed every ninety degrees along end rings of the birdcage body coil. In an embodiment, the surface coil is a single channel coil having a single receive channel for receiving first signals representing the first MRI data. In another embodiment, the surface coil may be a multi-channel coil having a plurality of receive channels for receiving first signals representing the first MRI data. In an embodiment, the birdcage body coil includes at least two receive channels for receiving second signals representing the second MRI data. In an embodiment, the target may include a torso of a patient.

In an embodiment, magnetic resonance imaging system is provided. The system includes a body coil assembly surrounding a target volume, the body coil assembly being configured to transmit a plurality of RF pulses to the target volume in a transmit mode, and a surface coil assembly arrange proximate to the target volume, the surface coil assembly being electrically coupled to a plurality of first receive channels configured to receive first RF signals from a target within the target volume. The body coil assembly is electrically coupled to a plurality of second receive channels configured to receive second RF signals from the target in a receive mode. The second RF signals are acquired by the volume coil and the first RF signals are acquired by the surface coil assembly simultaneously. In an embodiment, the magnetic resonance imaging system may include at least one low input pre-amplifier electrically coupled to the body coil assembly. The low input pre-amplifier is configured to generate high blocking impedance to reduce RF current in coil elements of the body coil assembly in the receive mode. In an embodiment, the high blocking impedance is generated by a parallel LC resonance circuit. In an embodiment, the at least one low input pre-amplifier is four low input pre-amplifiers electrically coupled to the body coil assembly at four points on the body coil assembly. In an embodiment, the body coil assembly is a birdcage body coil. In an embodiment, the four points are distributed every ninety degrees along end rings of the birdcage body coil. In an embodiment, the plurality of second receive channels is two second receive channels. In an embodiment, the system may also include a polarizing magnet configured to produce a longitudinal magnetic field B0 throughout the target volume. In an embodiment, the body coil is configured to produce a transverse magnetic field B1 that is generally perpendicular to B0 throughout the target volume.

In an embodiment, a method of parallel imaging for use with a magnetic resonance imaging apparatus is provided. The method includes the steps of transmitting a plurality of RF pulses to a target volume with a body coil operating in a body coil transmit mode, acquiring first magnetic resonance signals from a target within the target volume with a surface coil operating in a surface coil receive mode, reducing mutual couplings between the body coil and the surface coil with the body coil operating in a body coil receive mode, and acquiring second magnetic resonance signals from the target within the target volume with the body coil operating in the body coil receive mode, wherein acquisition of the first magnetic resonance signals and the second magnetic resonance signals occurs substantially simultaneously. In an embodiment, the step of reducing mutual couplings between the body coil and the surface coil includes generating a high blocking impedance in the body coil to reduce RF current in the body coil while acquiring the second magnetic resonance signals. In an embodiment, the body coil is a birdcage body coil. In an embodiment, the surface coil has a plurality of channels for receiving the first magnetic resonance signals and the birdcage body coil has at least two channels for receiving the second magnetic resonance signals.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope.

While the dimensions and types of materials described herein are intended to define the parameters of the invention, they are by no means limiting and are exemplary embodiments. Many other embodiments will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, terms such as “first,” “second,” “third,” “upper,” “lower,” “bottom,” “top,” etc. are used merely as labels, and are not intended to impose numerical or positional requirements on their objects. Further, the limitations of the following claims are not written in means-plus-function format and are not intended to be interpreted based on 35 U.S.C. §122, sixth paragraph, unless and until such claim limitations expressly use the phrase “means for” followed by a statement of function void of further structure.

This written description uses examples to disclose several embodiments of the invention, including the best mode, and also to enable one of ordinary skill in the art to practice the embodiments of invention, including making and using any devices or systems and performing any incorporated methods. The patentable scope of the invention is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

Since certain changes may be made in the above-described invention, without departing from the spirit and scope of the invention herein involved, it is intended that all of the subject matter of the above description or shown in the accompanying drawings shall be interpreted merely as examples illustrating the inventive concept herein and shall not be construed as limiting the invention.

What is claimed is:

1. A method of parallel imaging for use with a magnetic resonance imaging apparatus, the method comprising the steps of:
producing a longitudinal magnetic field B0 throughout a target volume;
producing a transverse magnetic field B1 that is generally perpendicular to B0 throughout the target volume;
transmitting a plurality of RF pulses to the target volume;
with a surface coil, acquiring first MRI data from a target within the target volume in response to the transmission of RF pulses; and
with a body coil, acquiring second MRI data from the target within the target volume in response to the transmission of RF pulses;
wherein acquisition of the first MRI data and the second MRI data occurs substantially simultaneously.

2. The method according to claim 1, further comprising the step of:
reducing mutual couplings between the body coil and the surface coil during MRI data acquisition.

3. The method according to claim 2, wherein:
the step of reducing mutual couplings between the body coil and the surface coil includes generating a high blocking impedance to reduce RF current in the body coil while receiving the second MRI data.

4. The method according to claim 3, wherein:
the body coil is a birdcage body coil.

5. The method according to claim 4, wherein:
the high blocking impedance is generated at four points on the birdcage body coil, the four points being distributed every ninety degrees along end rings of the birdcage body coil.

6. The method according to claim 4, wherein:
the surface coil is a single channel coil having a single receive channel for receiving first signals representing the first MRI data.

7. The method of according to claim 4, wherein:
the surface coil is a multi-channel coil having a plurality of receive channels for receiving first signals representing the first MRI data.

8. The method according to claim 7, wherein:
the birdcage body coil includes at least two receive channels for receiving second signals representing the second MRI data.

9. The method according to claim 1, wherein:
the target includes a torso of a patient.

10. A magnetic resonance imaging system, comprising:
a body coil assembly surrounding a target volume, the body coil assembly being configured to transmit a plurality of RF pulses to the target volume in a transmit mode; and
a surface coil assembly arrange proximate to the target volume, the surface coil assembly being electrically coupled to a plurality of first receive channels configured to receive first RF signals from a target within the target volume;
wherein the body coil assembly is electrically coupled to a plurality of second receive channels configured to receive second RF signals from the target in a receive mode; and
wherein the second RF signals are acquired by the volume coil and the first RF signals are acquired by the surface coil assembly simultaneously.

11. The magnetic resonance imaging system of claim 10, further comprising:
at least one low input pre-amplifier electrically coupled to the body coil assembly, the low input pre-amplifier being configured to generate high blocking impedance to reduce RF current in coil elements of the body coil assembly in the receive mode.

12. The magnetic resonance imaging system of claim 11, wherein:
the high blocking impedance is generated by a parallel LC resonance circuit.

13. The magnetic resonance imaging system of claim 11, wherein:
the at least one low input pre-amplifier is four low input pre-amplifiers electrically coupled to the body coil assembly at four points on the body coil assembly.

14. The magnetic resonance imaging system of claim 13, wherein:
the body coil assembly is a birdcage body coil.

15. The magnetic resonance imaging system of claim 14, wherein:
the four points are distributed every ninety degrees along end rings of the birdcage body coil.

16. The magnetic resonance imaging system of claim 15, wherein:
the plurality of second receive channels is two second receive channels.

17. The magnetic resonance imaging system of claim 10, further comprising:
a polarizing magnet configured to produce a longitudinal magnetic field B0 throughout the target volume.

18. The magnetic resonance imaging system of claim 17, wherein:
the body coil is configured to produce a transverse magnetic field B1 that is generally perpendicular to B0 throughout the target volume.

19. A method of parallel imaging for use with a magnetic resonance imaging apparatus, the method comprising the steps of:
transmitting a plurality of RF pulses to a target volume with a body coil operating in a body coil transmit mode;
acquiring first magnetic resonance signals from a target within the target volume with a surface coil operating in a surface coil receive mode;
reducing mutual couplings between the body coil and the surface coil with the body coil operating in a body coil receive mode; and
acquiring second magnetic resonance signals from the target within the target volume with the body coil operating in the body coil receive mode;
wherein acquisition of the first magnetic resonance signals and the second magnetic resonance signals occurs substantially simultaneously.

20. The method according to claim 19, wherein:
the step of reducing mutual couplings between the body coil and the surface coil includes generating a high blocking impedance in the body coil to reduce RF current in the body coil while acquiring the second magnetic resonance signals.

21. The method according to claim 19, wherein:
the body coil is a birdcage body coil.

22. The method according to claim 21, wherein:
the surface coil has a plurality of channels for receiving the first magnetic resonance signals; and
the birdcage body coil has at least two channels for receiving the second magnetic resonance signals.
